(19) United States
(12) Patent Application Publication
(10) Pub. No.: US 2012/0073502 A1
(43) Pub. Date: Mar. 29, 2012

(54) HEATER WITH LIQUID HEATING ELEMENT

(75) Inventors: Boris Volf, Hillsborough, NJ (US); Eric A. Armour, Pennington, NJ (US)

(73) Assignee: VEECO INSTRUMENTS INC., Plainview, NY (US)

(21) Appl. No.: 12/891,069

(22) Filed: Sep. 27, 2010

(51) Int. Cl. C23C 16/02; H05B 3/60

(52) U.S. Cl. 118/725; 392/311; 392/312

(57) ABSTRACT

A heater for a heating system of a chemical vapor deposition process includes a relatively highly emissive body and an electrically conductive heating element disposed within a passageway in the body. The heating element is constructed to melt below an operating temperature of the heater. The passageway is constructed to retain the melted heating element in a continuous path, so that an electrical current along the heating element may be maintained during operation of the heater. Various shapes and arrangements of the passageway within the body may be used, and the heating system may be constructed to provide multiple, independently controllable temperature zones.

### BACKGROUND OF THE INVENTION

The present invention relates to wafer processing apparatus, to heating systems for use in such processing apparatus, and to methods of heating using such heating systems.

Many semiconductor devices are formed by processes performed on a substrate. The substrate typically is slab of a crystalline material, commonly referred to as a “wafer.” Typically, the wafer is formed from a crystalline material, and is in the form of a disc. One common process for forming such a wafer is epitaxial growth.

For example, devices formed from compound semiconductors such as III-V semiconductors typically are formed by growing successive layers of the compound semiconductor using metal organic chemical vapor deposition or “MOCVD.” In this process, the wafers are exposed to a combination of gases, typically including a metal organic compound as a source of a group III metal, and also including a source of a group V element which flow over the surface of the wafer while the wafer is maintained at an elevated temperature. Typically, the metal organic compound and group V source are combined with a carrier gas which does not participate appreciably in the reaction as, for example, nitrogen. One example of a III-V semiconductor is gallium nitride, which can be formed by reaction of an organo gallium compound and ammonia on a substrate having a suitable crystal lattice spacing, as for example, a sapphire wafer. Typically, the wafer is maintained at a temperature on the order of 500-1200° C. during deposition of gallium nitride and related compounds.

Composite devices can be fabricated by depositing numerous layers in succession on the surface of the wafer under slightly different reaction conditions, as for example, additions of other group III or group V elements to vary the crystal structure and bandgap of the semiconductor. For example, in a gallium nitride based semiconductor, indium, aluminum or both can be used in varying proportion to vary the bandgap of the semiconductor. Also, p-type or n-type dopants can be added to control the conductivity of each layer. After all of the semiconductor layers have been formed and, typically, after appropriate electric contacts have been applied, the wafer is cut into individual devices. Devices such as light-emitting diodes (“LEDs”), lasers, and other electronic and optoelectronic devices can be fabricated in this way.

In a typical chemical vapor deposition process, numerous wafers are held on a device commonly referred to as a wafer carrier so that a top surface of each wafer is exposed at the top surface of the wafer carrier. The wafer carrier is then placed into a reaction chamber and maintained at the desired temperature while the gas mixture flows over the surface of the wafer carrier. It is important to maintain uniform conditions at all points on the top surfaces of the various wafers on the carrier during the process. Minor variations in composition of the reactive gases and in the temperature of the wafer surfaces cause undesired variations in the properties of the resulting semiconductor devices.

For example, if a gallium and indium nitride layer is deposited, variations in wafer surface temperature or concentrations of reactive gasses will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary. Thus, considerable effort has been devoted in the art heretofore towards maintaining uniform conditions.

One type of CVD apparatus which has been widely accepted in the industry uses a wafer carrier in the form of a large disc with numerous wafer-holding regions, each adapted to hold one wafer. The wafer carrier is supported on a spindle within the reaction chamber so that the top surface of the wafer carrier having the exposed surfaces of the wafers faces upwardly toward a gas distribution element. While the spindle is rotated, the gas is directed downwardly onto the top surface of the wafer carrier and flows across the top surface toward the periphery of the wafer carrier.

The wafer carrier is maintained at the desired elevated temperature by heating elements, typically electrically resistive radiant heating filaments disposed below the bottom surface of the wafer carrier. One example of such radiant heating elements is disclosed in U.S. Pat. No. 5,759,281, the disclosure of which is hereby incorporated by reference herein. Typical heating elements are maintained at a temperature above the desired temperature of the wafer surfaces, and heat is transferred from the heating elements to the bottom surface of the wafer carrier and flows upwardly through the wafer carrier to the individual wafers. The walls of the reaction chamber typically are maintained at temperatures substantially below the desired temperature of the wafer surfaces, and therefore heat is continually transferred from the wafer carrier and wafers to the walls. Thus, heat must be continually transferred from the heating element to the wafer carrier and wafers.

In certain reactors, a structure referred to as a “susceptor” is disposed between the heater and the wafer carrier, so that heat flows from the heating element to the susceptor and from the susceptor to the wafer carrier. In other reactors, referred to as “susceptorless” reactors as disclosed, for example, in U.S. Pat. No. 6,506,252, the disclosure of which is hereby incorporated by reference herein, the wafer carrier is disposed directly above the heating element, so that there is direct heat transfer between the heating element and the wafer carrier. In either type of reactor, a substantial proportion of the heat transfer from the heating element to the wafer carrier occurs by radiation. Because the rate of heat transfer by radiation is proportional to the fourth power of the temperature difference, the rate of heat transfer varies greatly with the temperature difference between the heating element and the wafer carrier. For example, in order to heat a wafer carrier to a temperature of 1200° C., the filaments may need to be heated to approximately 2100° C.

Filaments suitable for use at such extreme temperatures may be made from very expensive and rare materials such as rhenium. Other common filament materials, such as tungsten, can embrittle in the hydrogen-rich environment of the reaction chamber. Common radiant heating filaments may develop problems after repeated use. For example, the cyclical heating and cooling of the filaments that occurs from run-to-run of the processing apparatus causes expansion and contraction of the filaments. The expansion of the filaments during heating can cause the filament to bend or warp, which may lead to uneven heat transmission to the wafer carrier from particular portions of the filaments. Additionally, repeated expansion and contraction can cause the filament material to creep, due to recrystallization, which results in permanent deformation of the filaments and may lead to further uneven heating. Moreover, repeated cycling between expansion and contraction over a period of time may lead to eventual failure of the filaments.

The above problems can reduce the useful lifespan of current heating filaments, which may increase the costs of operating semiconductor processing apparatuses, as the heating elements may need to be replaced relatively frequently.

Although considerable effort has been devoted in the art heretofore to optimization of such systems, still further improvement would be desirable. In particular, it would be desirable to provide better and more efficient heating systems.

### BRIEF SUMMARY OF THE INVENTION

One aspect of the present invention provides a heating system. A heating system according to this aspect of the invention desirably includes a heater and a power source. The heater desirably includes a body having a passageway therein and an electrically conductive heating element disposed within the passageway. The power source is desirably operative to apply a sufficient electrical current to the heating element to maintain the heating element in a liquid state.

A further aspect of the invention provides a chemical vapor deposition apparatus incorporating a heating system as discussed above.

Another aspect of the invention provides a heater. A heater according to this aspect of the invention desirably includes a body having a passageway therein and an electrically conductive heating element disposed within the passageway. The heating element is desirably adapted to be a liquid at or below an operating temperature of the heater, and the passageway is desirably adapted to maintain the liquid of the heating element in a continuous path along the passageway.

Yet another aspect of the invention provides a method of operating a heater. A method according to this aspect of the invention desirably includes applying an electrical current to a heater. The heater has a heating element disposed within a passageway of a body. The electrical current desirably causes the heating element to heat up to an operating temperature at which the heating element is maintained in a liquid state. The method may include melting the heating element.

### BRIEF DESCRIPTION OF THE DRAWINGS

FIG. 1 is a perspective sectional view depicting a chemical vapor deposition apparatus in accordance with one embodiment of the invention.

FIG. 2 is a diagrammatic plan view of an embodiment of elements of the chemical vapor deposition apparatus illustrated in FIG. 1.

FIG. 3 is a diagrammatic sectional view taken along line 3-3 in FIG. 2.

FIG. 4 is a diagrammatic sectional view taken along line 4-4 in FIG. 2.

FIG. 5 is a diagrammatic sectional view depicting portions of elements of an apparatus according to a further embodiment of the invention.

FIG. 6 is a diagrammatic sectional view depicting portions of elements of an apparatus according to another embodiment of the invention.

### DETAILED DESCRIPTION

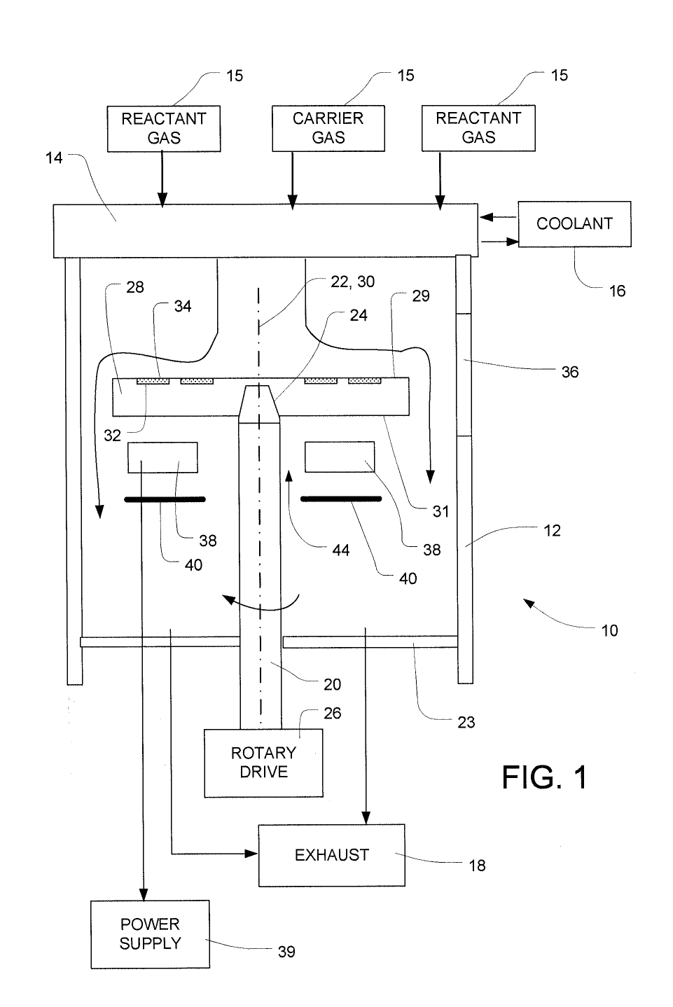

Referring to FIG. 1, a chemical vapor deposition apparatus 10 in accordance with one embodiment of the invention includes a reaction chamber 12 having a gas distribution element 14 arranged at one end of the chamber 12. The end of the chamber 12 having the gas distribution element 14 is referred to herein as the “top” end of the chamber 12. This end of the chamber typically, but not necessarily, is disposed at the top of the chamber in the normal gravitational frame of reference. Thus, the downward direction as used herein refers to the direction away from the gas distribution element 14; whereas the upward direction refers to the direction within the chamber, toward the gas distribution element 14, regardless of whether these directions are aligned with the gravitational upward and downward directions. Similarly, the “top” and “bottom” surfaces of elements are described herein with reference to the frame of reference of chamber 12 and element 14.

The gas distribution element 14 is connected to sources 15 of gases to be used in the wafer treatment process, such as a carrier gas and reactant gases (e.g., a metalorganic compound and a source of a group V metal). In a typical chemical vapor deposition process, the carrier gas can be nitrogen, and hence the process gas at the top surface of a wafer carrier can be predominantly composed of nitrogen with some amount of the reactive gas components. The gas distribution element 14 is arranged to receive the various gases and direct a flow of process gasses generally in the downward direction. The gas distribution element 14 desirably is also be connected to a coolant system 16 arranged to circulate a liquid through the gas distribution element 14 so as to maintain the temperature of the element at a desired temperature during operation. A similar coolant arrangement (not shown) can be provided for cooling the walls of chamber 12. Chamber 12 is also equipped with an exhaust system 18 arranged to remove spent gases from the interior of the chamber through ports (not shown) at or near the bottom of the chamber so as to permit continuous flow of gas in the downward direction from the gas distribution element.

A spindle 20 is arranged within the chamber so that the central axis 22 of the spindle 20 extends in the upward and downward directions. The spindle 20 is mounted to the chamber by a conventional rotary pass-through device (not shown) incorporating bearings and seals, so that the spindle can rotate about the central axis 22 while maintaining a seal between the spindle 20 and the bottom 23 of the chamber 12. The spindle 20 has a fitting 24 at its top end, i.e., at the end of the spindle closest to the gas distribution element 14. In the particular embodiment depicted, the fitting 24 is a generally conical element tapering toward the top end of the spindle 20. The spindle 20 is connected to a rotary drive mechanism 26 such as an electric motor drive, which is arranged to rotate the spindle about the central axis 22. The spindle 20 can also be provided with internal coolant passages extending generally in the axial directions of the spindle within the gas passageway. The internal coolant passages can be connected to a coolant source, so that a fluid coolant can be circulated by the source through the coolant passages and back to the coolant source.

In the operative condition depicted in FIG. 1, a wafer carrier 28 is mounted on the fitting 24 of the spindle 20. The wafer carrier 28 is desirably detachably mounted on the fitting 24. The wafer carrier includes a body generally in the form of a circular disc having a central axis 30 coincident with the axis 22 of the spindle 20. The wafer carrier 28 is preferably formed from materials which do not contaminate the CVD process and which can withstand the temperatures encountered in the process. For example, the wafer carrier 28 may be formed largely or entirely from materials such as graphite, silicon carbide, molybdenum, aluminum nitride, boron nitride (e.g., pyrolitic boron nitride), or other refractory materials. The carrier 28 has generally planar top 29 and bottom 31 surfaces extending generally parallel to one another and generally perpendicular to the central axis 30 of the disc. The carrier 28 also has a plurality of generally circular wafer-holding pockets 32 extending downwardly into the carrier 28 from the top surface 29 thereof, each pocket adapted to hold a wafer 34. In one example, the wafer carrier 28 can be between about 180 mm to about 1000 mm in diameter.

A wafer 34, such as a disc-like wafer formed from sapphire, silicon carbide, or other crystalline substrate, may be disposed within each pocket 32 of the wafer carrier 28. Typically, each wafer 34 has a thickness which is small in comparison to the dimensions of its major surfaces. For example, a circular wafer 34 about 2 inches (40 mm) in diameter may be about 430 μm thick or less. Each wafer 34 is disposed with a top surface thereof facing upwardly, so that the top surface is exposed at the top of the wafer carrier 28.

The chamber 12 is provided with a port 36 leading to an antechamber (not shown), so that the wafer carrier 28 may be moved into and out of the chamber 12. A shutter (not shown) may also be provided for closing and opening the port 36. The apparatus 10 can further include a loading mechanism (not shown) capable of moving the wafer carrier 28 from the antechamber into the chamber 12 and engaging the wafer carrier 28 with the spindle 20 in the operative condition, and also capable of moving the wafer carrier 28 off of the spindle 20 and into the antechamber.

A heater 38 is mounted within the chamber 12 and surrounds the spindle 20 below the fitting 24. The heater 38 is powered by a power supply 39 and is arranged to transfer heat towards the bottom surface 31 of the wafer carrier 28, principally by radiant heat transfer. Heat applied to the bottom surface 31 of the wafer carrier 28 preferably flows upwardly through the wafer carrier 28 towards the top surface 29 thereof, where it heats the wafers 34 and the process gasses passing over the top surface 29 of the wafer carrier 28. One or more heat shields 40 may also be mounted below the heater 38.

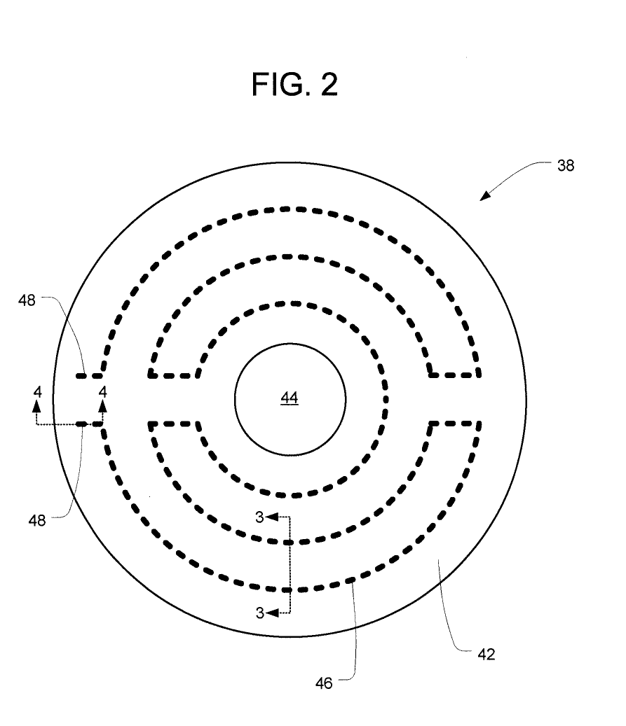

FIGS. 2-4 diagrammatically illustrate a preferred construction for heater 38. The heater 38 includes a body 42 in the shape of an annular disc defining a central open portion 44 sized to surround the spindle 20. The heater 38 also includes at least one heating element 46 disposed within the body 42. The heating element 46 preferably follows a serpentine path around the body 42 between two end portions 48, where the heating element 46 may be connected to a source of electrical current.

The body 42 is preferably constructed of a material that is thermally conductive and electrically non-conductive. Providing an electrically non-conductive body desirably avoids potential short-circuiting, where the electrical current bypasses part of the serpentine path of the heating element 46 and passes through the material of the body 42. A preferred material may be CVD or sintered silicon carbide, which can be electrically non-conductive, depending on the doping properties.

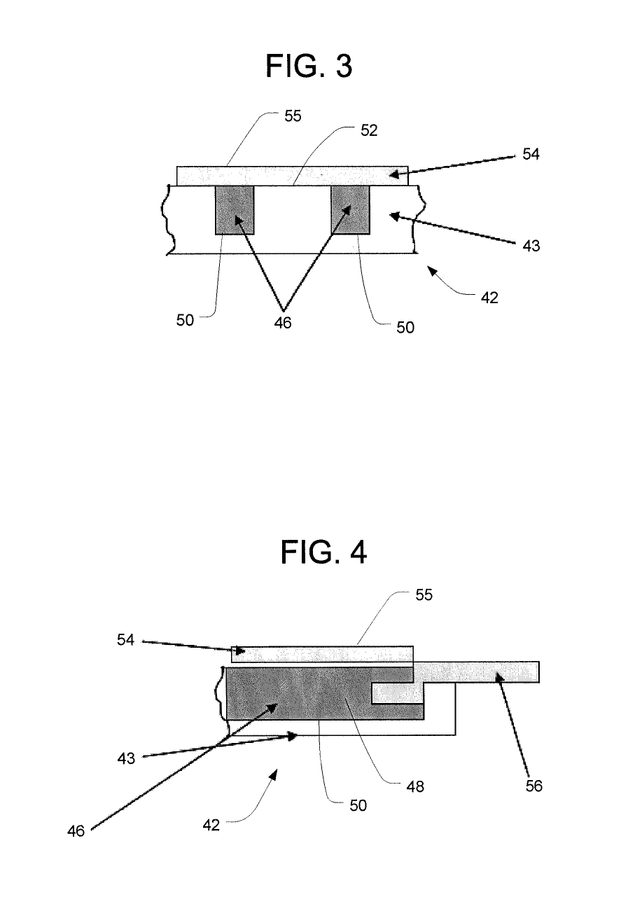

As shown in FIG. 3, the body 42 includes a main section 43 having an upper surface 52. The heating element 46 may be located within a channel 50 formed in the main section 43 of the body 42. The channel may be in the form of a groove formed in the upper surface 52 of the main section 43. The body 42 also preferably includes a cover 54 extending over at least a portion of the upper surface 52, so as to cover the channel 50. The cover 54 may define all or a part of a top surface 55 of the body 42 facing towards the wafer carrier 28.

The top surface 55 of body 42 desirably has a high emissivity. For example, the cover 54 defining top surface 55 desirably is formed from a material having high emissivity, such as black ceramic or silicon carbide, so that heat generated by the heating element 46 may be radiated particularly efficiently from the top surface of the body 42. The main section 43 may be formed from a similar material, and also may have high emissivity. Alternatively, the main section 43 may have a lower emissivity than the cover to restrict heat loss from the bottom and edges of the main section. Emissivity is a dimensionless quantity representing the ratio of energy radiated by a unit area of the material to the energy radiated by a unit area of a theoretical “black body” at the same temperature. The material forming the top surface of the body 42 preferably has a higher emissivity than typical radiant heating filaments used in the prior art. For example, while a prior art filament may have an emissivity of about 0.37, the emissivity of body 42, and particularly top surface 55, desirably is at least about 0.5, and desirably at least about 0.7. The preferred black ceramic or silicon carbide body 42 preferably has an emissivity of approximately 0.8.

Due to the relatively large, continuous top surface 55 of the annular body 42, the body 42 preferably has a higher surface area radiating towards the wafer carrier 28 than the filaments used in the prior art, which typically have open space between each of the strands of filament. Due to both the higher emissivity and the higher surface area of the body 42 compared to the prior art radiant heating filaments, the heater 38 disclosed herein is preferably more efficient than the filaments used in the prior art (i.e., the heater 38 will radiate more power at a particular temperature than the prior art filaments). Thus, in order to radiate the same power as prior art filaments, the temperature of the heater 38 may be set lower than the prior art filaments. For example, at a top surface temperature of approximately 1600° C., the heater 38 may produce approximately the same radiant heat transfer to the wafer carrier as a typical arrangement of filaments at 2100° C. Therefore, the construction of the heater 38 disclosed herein preferably allows for a reduction in the temperature of the heating portion of the apparatus. This desirably reduces energy usage by the processing apparatus 10 and also extends the lifespan of the heating system components.

The structure of the body 42, with its channel 50 for receiving the heating element 46, may also reduce some of the problems associated with the prior art heating filaments. For example, the body 42, the heating element 46, and top surface 55 preferably remain substantially flat and parallel to the plane of the wafer carrier 28 over the lifetime of the heating system, thus avoiding the creep and resulting uneven heating of common prior art radiant filaments.

The heating element 46 is preferably constructed of a material that melts below even the reduced operating temperature of the heater 38. Stated another way, the power supply 39 is arranged to provide a current which is sufficient to maintain the heater at an operating temperature above the solidus temperature of the material of heating element 46, so that the heating element is in an at least partially liquid state. Desirably, the operating temperature is above the liquidus temperature of the material of heating element 46, so that the heating element is entirely in a liquid state. Desirably, the solidus temperature of the heating element is above room temperature (20° C.), more preferably above about 40° C. so that the heating element is in a solid state during handling, shipping, and assembly of the apparatus, and the heating element melts during operation. A preferred material for the heating element 46 may be tin, however many other materials could be used. For example, an alloy, such as a gold-based alloy, may have beneficial properties. Desirably the material used will have a melting temperature below approximately 750° C. and will have a vapor pressure at operating temperature that is relatively low compared to the operating pressure within the chamber 12. An exemplary operating temperature of the heater 38 may be between about 1500 and 1700° C., while operating pressures within the chamber 12 may be between about 100 Torr (about 13,000 pascals) and about 700 Torr (about 93,000 pascals). A preferred material for the heating element 46 will desirably have a vapor pressure below about 25 Torr (about 3,300 pascals) up to a temperature of about 2000° C. More preferably, the material has a vapor pressure below 10 Torr (about 1,300 pascals) up to that temperature. As shown in FIG. 1, the heater 38 is disposed below the wafer carrier 28, and thus lies between the wafer carrier and the connection to the exhaust system 18. Thus, the process gasses passing downstream within the chamber will tend to carry any vapor evolved from the heating element away from the wafer carrier. Thus, although the material preferably has relatively low vapor pressure at operating temperature, that property is not critical, since any metal vapor evolved form the heating element will likely never reach the area above the wafer carrier, where it could affect the process gases and the wafers.

By selecting a material that melts below the operating temperature of the heater, some of the problems associated with the prior art heating filaments may be avoided. For example, the heating element 46 may melt before it thermally expands to a significant degree, thus avoiding the warping and bending of prior art heating filaments. The melting of the heating element 46 also desirably reduces the need to design the heating element 46 and the body 42 to withstand any hoop stresses resulting from different thermal expansion coefficients of those components. Another benefit of the heating element 46 being a liquid at operating temperature is that it results in a very good thermal contact between the heating element 46 and the surface defining channel 50 of the body 42.

The channel 50 in the body 42 is desirably shaped such that, as the heating element 46 melts, the liquid material is retained in a continuous path from one end 48 to the other, so that the electrical connection between the ends 48 can be maintained. Electrodes 56, which provide an electrical current to the heating element 46 from the power supply 39, are preferably designed to be submerged under the liquid material in each end portion 48, as shown in FIG. 4.

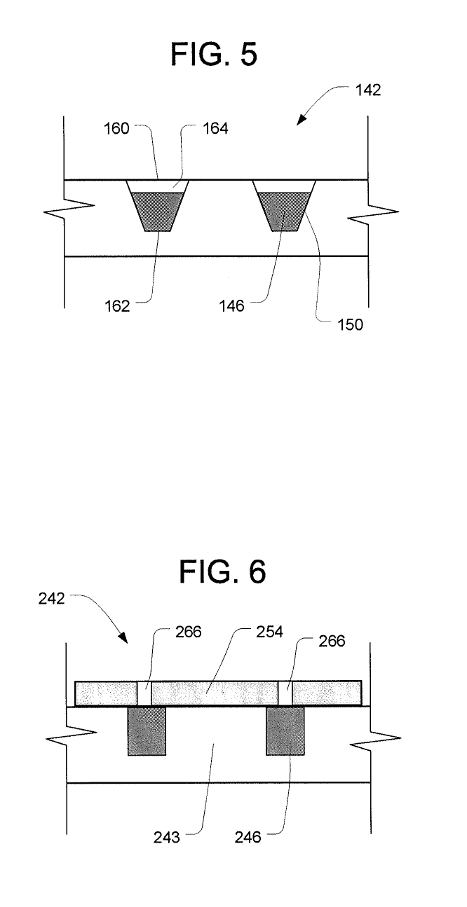

Although the channel 50 is illustrated in FIG. 4 as having a generally rectangular shape, other shapes may also be used. For example, a channel 150 in an alternative body 142 may have a trapezoidal shape, as shown in FIG. 5. In FIG. 5, the wider base 160 of the trapezoid is located above the narrower base 162, however, the reverse design may also be useful. In other alternative channel designs, the profile of the channel may have a curved or circular shape.

The design of the heater body 42 need not include a cover 54, as shown in the embodiment of FIG. 5, in which similar reference numerals to those used in FIGS. 1-4 denote similar elements. In this case, if a cover 54 is not provided, the heating element 146 may be exposed to the space between the body 142 and the wafer carrier 28. In another alternative, instead of having a cover 54, the channel may be disposed entirely within the interior of the heater body, in which case the material of the body surrounding the channel on the upper side may take the place of a cover.

In order to allow for expansion of the heating element 146 during temperature increase and melting, a gap 164 may be provided between the top 160 of the channel 150 and the heating element 146. Such a gap may be used in connection with any design of the channels, and may be provided whether or not a cover 54 is used. A cover 254 for a heater body 242 may also include openings 266, as shown in FIG. 6, to allow for the expansion of the heating element 246. Although the openings 266 need not pass entirely through the cover 254, pass-through openings 266 may be strategically placed in particular locations where lower heat transfer to the wafer carrier may be desirable, since the heating element 246 may have a lower emissivity than the material of the main portion of the body 243 and the cover 254. In yet another alternative design, radially oriented passages (not shown) may be provided in the body to allow for expansion of the liquid heating element.

A heating system as shown in the present disclosure may be constructed as a multiple-zone heating system, in which the temperatures of different zones within the apparatus are independently controllable, in order to improve temperature uniformity along the surface of the wafer carrier. For example, two or more independently operable heaters having separate bodies may be provided below the wafer carrier, to create multiple annular heating zones below the wafer carrier. As an example of a two-zone system, an outer annular heater may have a central open portion shaped larger than an outer diameter of an inner annular heater, so that the inner heater can be received within the outer heater. In a further arrangement, a single heater body can be provided with two or more separate channels in two or more separate zones such as an inner zone and an outer annular zone surrounding the inner zones. Each channel may have a separate heating element. The power supply may be connected to the separate heating elements and may control the temperatures of the separate zones independently of one another.

Three or more annular zones may be created in a similar manner to that described above. Additionally, the types of heaters used in each zone may be varied, depending on the desired characteristics of the heating system. For example, the heater in one or more zones may include a body having a channel for receiving a meltable heating element, similar to the embodiments described above, while the heater in one or more of the other zones may include radiant heating filaments, similar to some prior art systems. Any combination of such heater types may be used.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A heating system, comprising:
a heater, including:
a body having a passageway therein; and
an electrically conductive heating element disposed within the passageway; and
a power source operative to apply a sufficient electrical current to said heating element to maintain said heating element in a liquid state.

2. The heating system of claim 1, wherein the heating element comprises a material having a melting point below 750° C.

3. The heating system of claim 2, wherein the heating element comprises a material having a vapor pressure less than 25 Torr at 2000° C.

4. The heating system of claim 1, wherein the heating element comprises tin.

5. The heating system of claim 1, wherein the body has a surface having an emissivity of approximately 0.7 or higher.

6. The heating system of claim 1, wherein the body comprises silicon carbide.

7. The heating system of claim 1, wherein the body includes a main section having an upwardly-facing upper surface and the passageway is a groove formed in the upper surface of the main section.

8. The heating system of claim 7, wherein the body further includes a cover overlying the upper surface of the main section and covering the groove.

9. The heating system of claim 8, wherein the cover is constructed of the same material as the body.

10. The heating system of claim 1, wherein the heating element is smaller than the passageway, such that a gap is defined within the passageway outside of the heating element.

11. The heating system of claim 1, wherein the passageway has a rectangular profile.

12. The heating system of claim 1, wherein the passageway has a trapezoidal profile.

13. The heating system of claim 1, wherein the body includes at least one opening extending from the passageway, the opening being adapted to receive a portion of the heating element when the heating element expands.

14. A chemical vapor deposition apparatus, comprising:
a reaction chamber;
a wafer carrier mounted within the reaction chamber; and
a heating system as recited in claim 1, wherein the heater is arranged to transmit heat to the wafer carrier.

15. The chemical vapor deposition apparatus of claim 14, wherein the heater is mounted below the wafer carrier.

16. The chemical vapor deposition apparatus of claim 14, wherein the wafer carrier is mounted to a rotatable spindle.

17. A heater, comprising:
a body having a passageway therein; and
an electrically conductive heating element disposed within the passageway, the heating element being adapted to be a liquid at or below an operating temperature of the heater;
wherein the passageway is adapted to maintain the liquid of the heating element in a continuous path along the passageway.

18. A method of operating a heater, comprising:
applying an electrical current to a heater having a heating element disposed within a passageway of a body, the electrical current causing the heating element to heat up to an operating temperature at which the heating element is maintained in a liquid state.

19. The method of claim 18, further comprising melting the heating element.

20. The method of claim 18, further comprising transmitting heat from the heater to a wafer carrier mounted within a reaction chamber of a chemical vapor deposition apparatus.

21. The method of claim 20, further comprising rotating the wafer carrier about an axis substantially perpendicular to the wafer carrier.

22. The method of claim 18, wherein the operating temperature is below approximately 2000° C.
